(19) United States
(12) Patent Application Publication
(10) Pub. No.: US 2026/0186063 A1
(43) Pub. Date: Jul. 2, 2026

(54) METHOD AND SYSTEM FOR MEASURING INTERNAL RESISTANCE OF BATTERY

(71) Applicant: Samsung Electronics Co., Ltd., Suwon-si (KR)

(72) Inventors: Dongjoon Lee, Suwon-si (KR); Hyunpyo Lee, Suwon-si (KR); Chanhyuk Lim, Suwon-si (KR)

(21) Appl. No.: 19/368,127

(22) Filed: Oct. 24, 2025

(30) Foreign Application Priority Data
Dec. 31, 2024 (KR) 10-2024-0202516

(51) Int. Cl. G01R 31/389; G01R 31/3835; H01M 10/42; H02J 7/00

(52) U.S. Cl. CPC G01R 31/389; G01R 31/3835; H01M 10/425; H01M 2010/4271; H02J 7/80

(57) ABSTRACT

Provided are a method and system for measuring an internal resistance of a battery. The method includes obtaining an open circuit voltage (OCV) of the battery in an equilibrium state, obtaining a plurality of closed circuit voltages (CCVs) over time while charging or discharging the battery by using a constant current for 1 second or less, and determining an internal resistance of the battery by using the OCV and the plurality of CCVs.

### CROSS-REFERENCE TO RELATED APPLICATION

This application is based on and claims priority to Korean Patent Application No. 10-2024-0202516, filed on Dec. 31, 2024, in the Korean Intellectual Property Office, and all the benefits accruing therefrom under 35 U.S.C. § 119, the disclosure of which is incorporated by reference herein in its entirety.

### BACKGROUND

### 1. Field

The disclosure relates to a method and system for measuring an internal resistance of a battery.

### 2. Description of the Related Art

Demands for portable electronic products such as laptops, video cameras, portable phones, etc., have increased rapidly. Also, as the development of energy storage batteries, robots, satellites, etc., is rapidly advancing, research on high-performance secondary batteries that are repeatedly chargeable and dischargeable has been actively pursued.

In particular, as carbon energy is gradually depleted and interest in an environment is increasing, demands for hybrid vehicles and electric vehicles are gradually increasing around the world. As the hybrid vehicles or the electric vehicles use charging/discharging energy of battery packs to obtain vehicle driving power, the hybrid vehicles or the electric vehicles have excellent fuel efficiency and do not emit or reduce pollutants in comparison to vehicles using engines.

As described above, the batteries are used in various mobility devices such as vehicles, and thus need to be charged or discharged safely.

### SUMMARY

The disclosure provides a method and system for measuring an internal resistance of a battery, which is a parameter used in charging/discharging of the battery.

Additional aspects will be set forth in part in the description which follows and, in part, will be apparent from the description, or may be learned by practice of the presented embodiments of the disclosure.

According to an aspect of the disclosure, a method of measuring an internal resistance of a battery includes obtaining an open circuit voltage (OCV) of the battery in an equilibrium state, obtaining a plurality of closed circuit voltages (CCVs) over time while charging or discharging the battery by using a constant current for 1 second or less, and determining an internal resistance of the battery by using the OCV and the plurality of CCVs.

The battery may enter the equilibrium state after a lapse of 20 minutes or more from stop of an operation of the battery.

The obtaining of the plurality of CCVs may include obtaining an initial CCV within 50 milliseconds or less after providing the constant current to the battery.

The obtaining of the CCV may include obtaining the plurality of CCVs at intervals of a specific time after start of charging or discharging of the battery using the constant current.

The specific time may be 20 milliseconds or less.

The constant current may differ with a state of charge (SOC) of the battery.

The constant current may be in inverse proportion to the SOC of the battery.

The constant current may be 0.4 C-rate to 3 C-rate.

The determining of the internal resistance of the battery may include obtaining a resistance profile with respect to time by using the OCV and the plurality of CCVs, converting the resistance profile with respect to time into a resistance profile with respect to capacitance, and determining the internal resistance of the battery by using the resistance profile with respect to capacitance.

The resistance profile with respect to capacitance may include a first region in which a resistance change rate difference between adjacent resistances is a reference value or more and a second region in which the resistance change rate difference is less than the reference value, and the internal resistance of the battery may fall within a resistance range corresponding to the first region.

A difference between a maximum resistance and a minimum resistance in the resistance range corresponding to the first region may be 1 ohm Ω) or less.

In the resistance profile with respect to capacitance, the first region may have a capacitance less than that of the second region.

The first region may be a curved region, and the second region may be a straight region.

The internal resistance of the battery may fall within a resistance range corresponding to a capacitance before 1/1000 of a total capacitance of the battery in the resistance profile with respect to capacitance.

The determining of the internal resistance of the battery may include determining a resistance profile with respect to time by using the OCV and the plurality of CCVs, obtaining a ratio of a time-specific resistance change rate to an initial resistance change rate from the resistance profile with respect to time, and determining the internal resistance of the battery by using the ratio of the time-specific resistance change rate to the initial resistance change rate.

The internal resistance of the battery may be a minimum resistance in which the ratio of the time-specific resistance change rate to the initial resistance change rate is a reference value or less.

The reference value may be 0% to 30%.

According to another aspect of the disclosure, a battery management system includes a measurement unit configured to measure a closed circuit voltage (CCV) of a battery in an equilibrium state and measure a plurality of closed circuit voltages (CCVs) of the battery over time for a selected time during which the battery is charged or discharged with a constant current and a processor configured to obtain a resistance profile with respect to capacitance by using the OCV and the plurality of CCVs and determine an internal resistance of the battery from the resistance profile with respect to capacitance.

The selected time may be 1 second or less.

The constant current may be 0.4 C-rate to 3 C-rate.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 schematically shows a battery pack, including a battery management system according to an embodiment;

FIG. 2 is a flowchart of a method of measuring an internal resistance of a battery, according to an embodiment;

FIG. 3A illustrates a graph showing resistance (ohm, Ω) versus capacity (milliampere-hour, mAh), which exhibits a result of measuring a resistance profile with respect to capacitance for a battery of 5 mAh having a charging state of 70%, according to an embodiment;

FIG. 3B illustrates a graph showing resistance (ohm, Ω) versus capacity (milliampere-hour, mAh), which exhibits a result of measuring a resistance profile with respect to capacitance for a battery of 5 mAh having a charging state of 90%, according to an embodiment;

FIG. 3C illustrates a graph showing impendence Z″ (ohm, Ω) versus impendence Z′ (ohm, Ω), which exhibits a result of measuring a resistance of a battery used in FIGS. 3A and 3B using electrochemical impedance spectroscopy (EIS);

FIG. 4A illustrates a graph showing resistance (milliohm, mΩ) versus capacity (milliampere-hour, mAh), which exhibits a result of obtaining a resistance profile with respect to capacitance for a battery of 5 Ah having a charging state of 10%, according to an embodiment;

FIG. 4B illustrates a graph showing resistance (milliohm, mΩ) versus capacity (milliampere-hour, mAh), which exhibits a result of obtaining a resistance profile with respect to capacitance for a battery of 5 Ah having a charging state of 20%, according to an embodiment;

FIG. 4C illustrates a graph showing impendence Z″ (milliohm, mΩ) versus impendence Z′ (milliohm, mΩ), which exhibits a result of measuring a resistance of a battery, used in FIGS. 4A and 4B, using EIS;

FIG. 5A illustrates a graph showing resistance change rate/initial resistance change rate*100 (percent, %) versus resistance (ohm, Ω) which exhibits a result of obtaining a ratio of a time-specific resistance change rate to an initial resistance change rate from a battery of 5 mAh having a charging state of 70%, according to an embodiment; and

FIG. 5B illustrates a graph showing resistance change rate/initial resistance change rate*100 (percent, %) versus resistance (ohm, Ω), which exhibits a result of obtaining a ratio of a time-specific resistance change rate to an initial resistance change rate from a battery of 5 mAh having a charging state of 90%, according to an embodiment.

### DETAILED DESCRIPTION

Reference will now be made in detail to embodiments, examples of which are illustrated in the accompanying drawings, wherein like reference numerals refer to like elements throughout. In this regard, the current embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a method and system for measuring an internal resistance of a battery according to various embodiments will be described in detail with reference to the accompanying drawings. In the drawings, like reference numerals denote like components, and sizes of components in the drawings may be exaggerated for convenience of explanation.

Singular forms may include plural forms unless apparently indicated otherwise contextually. In case that a portion is referred to as “comprises” a component, the portion may not exclude another component but may further include another component unless stated otherwise.

The term used herein such as “unit” or “module” indicates a unit for processing at least one function or operation, and may be implemented in hardware, software, or in a combination of hardware and software.

Certain executions described herein are examples, not limiting the technical scope of the disclosure in any way. For the brevity of the specification, the description of conventional electronic configurations, control systems, software, and other functional aspects of the systems may be omitted.

Connections of lines or connection members between components shown in the drawings are illustrative of functional connections and/or physical or circuit connections, and in practice, may be represented as alternative or additional various functional connections, physical connections, or circuit connections.

The use of the terms of “the above-described” and similar indicative terms may correspond to both the singular forms and the plural forms.

Operations constituting a method may be performed in any suitable order unless it is explicitly stated that they should be performed in an order they are described. The use of all terms (for example, etc.) is only to describe the technical spirit in detail, and the scope of rights is not limited by these terms unless limited by the claims.

An expression such as “at least one” preceding a list of elements limits the entire list of elements, but does not limit any individual element in the list. For example, expressions such as “at least one of A, B, and C” or “at least one selected from the group consisting of A, B, and C” may be interpreted as A only, B only, C only, or any combination of two or more of A, B, and C, such as ABC, AB, BC, and AC.

Where “approximately” or “substantially” is used in connection with a numerical value, the related numerical value may be interpreted as including a manufacturing or operating deviation (e.g., ±10%, or ±5%, or ±3%,) around the stated numerical value. Where the terms “generally” and “substantially” are used in relation to geometric shapes, it may be intended that no geometric precision is required and that tolerance for shapes is within the scope of the current embodiment. Regardless of whether a value or shape is limited to “about” or “substantially,” such a value or shape may be interpreted as including a manufacturing or operating variation (e.g., ±10%, or ±5%, or ±3%,) around the stated numerical value.

Terms such as “first”, “second”, and the like may be used to describe various elements, but the elements should not be limited to those terms. These terms may be used to distinguish one element from another element.

The use of all examples or exemplary terms is only to describe the technical spirit in detail, and the scope is not limited by these examples or terms unless limited by the claims.

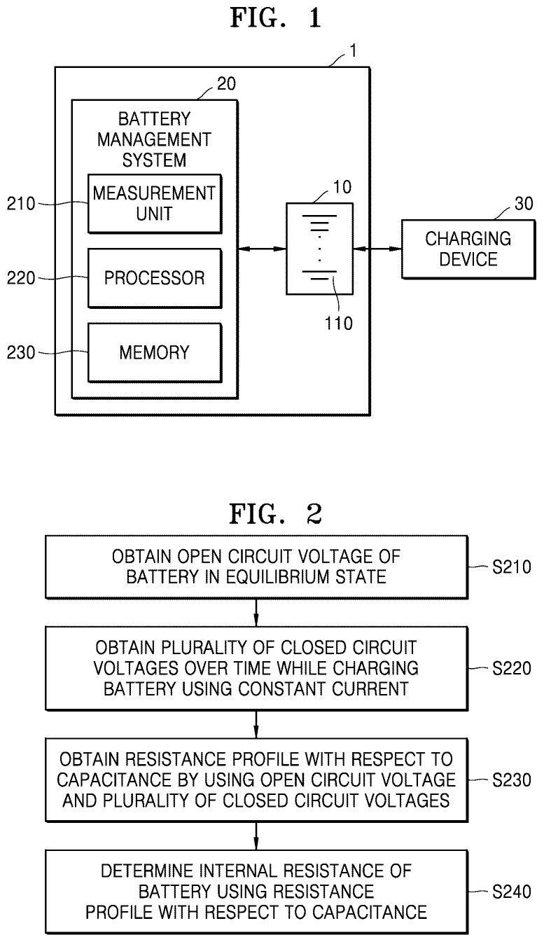

FIG. 1 schematically shows a battery pack 1 according to an embodiment.

Referring to FIG. 1, the battery pack 1 may include a battery 10 and a battery management system 20. The battery management system 20 may perform control and management to prevent over-charging and over-discharging by monitoring voltage, current, temperature, etc., of the battery 10.

The battery 10 may include at least one battery cell 110, which may be a chargeable secondary battery. In some embodiments, each battery cell 110 may include at least one selected from a group including a nickel-cadmium battery, a lead acid battery, a nickel metal hydride battery (NiMH), a lithium ion battery, a lithium polymer battery, etc.

The number of battery cells 110 included in the battery 10 and the connection scheme thereof may be determined based on the power amount, voltage, etc., required for the battery pack 1. While it is shown in FIG. 1 that the battery cells 110 included in the battery 10 are connected in series, the battery cells 110 may be connected in parallel or both in series and in parallel. The battery 10 may include one battery cell 110.

In an embodiment, the battery 10 or each of the at least one battery cell 110 included in the battery 10 may be a target for internal resistance measurement. In an embodiment, a method of measuring an internal resistance of one battery 10 has been described, but this method may be equally applied to a method of measuring an internal resistance of each of the plurality of battery cells 110 included in the battery 10.

Although not shown in FIG. 1, the battery pack 1 may include a pair of pack terminals to which an electric load or a charging device 30 is connectable. The battery pack 1 may further include a battery protection circuit, a fuse, a current sensor, etc.

The battery management system 20 may include a measurement unit 210 configured to measure one or more parameters of the battery 10, a processor 220 configured to control the battery 10, and a memory 230 in which information about the battery 10, a control program, etc., are stored.

The measurement unit 210 may measure at least one parameter of the battery 10. In some embodiments, the measurement unit 210 may measure an open circuit voltage (OCV) and a closed circuit voltage (CCV) of the battery 10 to measure the internal resistance of the battery 10. The measurement unit 210 may be electrically connected to opposite ends of the battery 10. The measurement unit 210 may be electrically connected to the processor 220 to exchange electrical signals with the processor 220. The measurement unit 210 may measure a voltage across the opposite ends of the battery 10 with a time interval and transmit information about the measured voltage to the processor 220, under control by the processor 220. The processor 220 may determine a voltage of the battery 10 from a signal output from the measurement unit 210. The measurement unit 210 may include a voltage measurement circuit generally used in this field.

The processor 220 may control and manage the battery 10 to prevent over-charging and over-discharging of the battery 10. In some embodiments, the processor 220 may determine the internal resistance of the battery 10. The processor 220 known in this field may be implemented in a form selectively including a processor, an application-specific integrated circuit (ASIC), another chipset, a logic circuit, a register, a communication modem, and/or a data processing device, etc., known in this field.

The processor 220 may perform basic arithmetic, logic, and input/output operations, and execute program code stored in the memory 230. The processor 220 may store data in the memory 230 or load data stored in the memory 230.

The memory 230 may include a permanent mass storage device, such as random access memory (RAM), read only memory (ROM), and a disk drive, as a recording medium readable by the processor 220. The memory 230 may store an operating system and at least one program or application code. The memory 230 may store program code for measuring the internal resistance according to an embodiment. The memory 230 may store data generated by measuring at least one parameter of the battery 10. In some embodiments, the data may include charging/discharging current, terminal voltage and/or temperature of the battery 10.

The battery management system 20 may further include a communication module for communication with another device such as an electronic control device of a vehicle, a controller of the charging device 30, etc. Some functions of the battery management system 20, e.g., a function of the processor 220, may be performed in an external device (e.g., the charging device 30, an external server, etc.) that may communicate with the battery management system 20, and the battery management system 20 may receive a result through the communication module.

A resistance of the battery 10 may be determined by materials included in the battery 10 and a physical and chemical reaction between materials. In some embodiments, the resistance of the battery 10 may be divided into a bulk resistance based on electric properties of materials included in the battery 10 such as ionic conductivity of an electrolyte included in the battery 10 and resistance properties of a separator, a contact resistance based on contact between the materials included in the battery 10, a charge transport resistance occurring when electric charges move at an electrode interface, a diffusion resistance due to ion diffusion in the battery 10, etc.

The diffusion resistance may be changed by current or voltage in charging or discharging, whereas the other resistances may be almost fixed values in charging or discharging. Among the resistances of the battery 10, an almost fixed value in charging or discharging of the battery 10 may be referred to as an internal resistance, and a resistance changeable by current or voltage in charging or discharging of the battery 10 may be referred to as a variable resistance. The sum of the internal resistance and the variable resistance may be referred to as the total resistance of the battery 10.

The internal resistance may increase in case that charging/discharging of the battery 10 is repeated. In case that the battery 10 is charged without considering the internal resistance, a fire may occur in the battery 10. Thus, it is necessary to accurately measure the internal resistance of the battery 10 and charge or discharge the battery 10 based on the measured internal resistance.

Generally, the internal resistance may be comparatively measured using electrochemical impedance spectroscopy (EIS). However, the EIS may have a limitation in application to the battery management system 20 due to high price, and may be difficult to apply to the battery 10 of high capacity. An OCV may also be measured after application of constant current, but the accuracy may be degraded due to a high deviation with respect to the magnitude of applied current.

The resistance of the battery 10 may be measured using the CCV. By using low-volume constant current, resistance measurement for the battery 10 may not be accurate. By measuring a CCV for several seconds or longer, the resistance of the battery 10 may include a variable resistance as well as the internal resistance such that the internal resistance may not be accurately measured.

In an embodiment, the battery management system 20 may measure the internal resistance of the battery 10 by using the OCV and the CCV obtained by application of the high-volume constant current to the battery 10 for a short time.

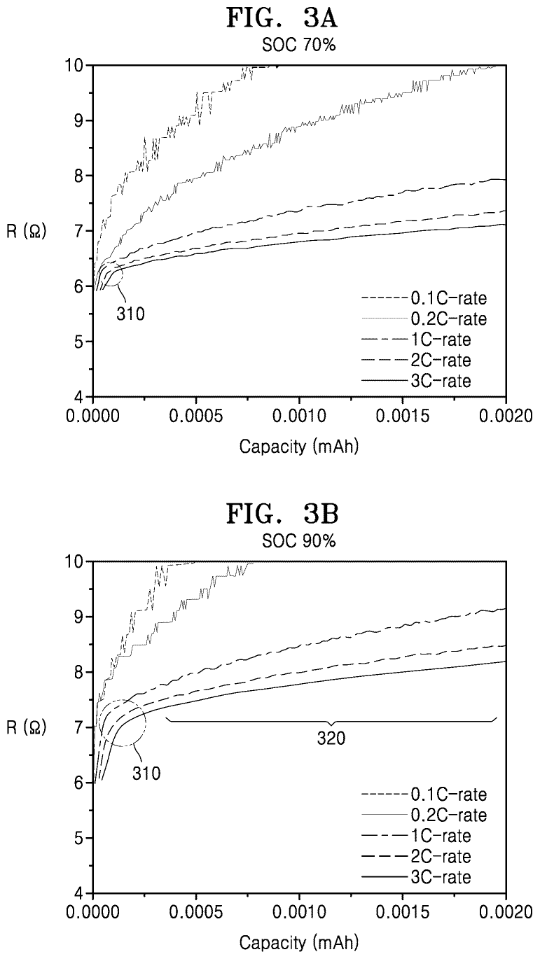

FIG. 2 is a flowchart of a method of measuring an internal resistance of a battery, according to an embodiment.

The processor 220 may obtain an OCV of the battery 10 in an equilibrium state, in operation S210. The battery 10 may enter the equilibrium state in case that an operation of charging or discharging is stopped for a specific time or longer. In some embodiments, the battery 10 may enter the equilibrium state in case that there is no operation for about 20 minutes or about 30 minutes. However, the disclosure is not limited thereto. The equilibrium state of the battery 10 may differ with capacity, type, or previously charged or discharged current or voltage of the battery 10. The measurement unit 210 may measure the OCV of the battery 10 in the equilibrium state and transmit the same to the processor 220.

The processor 220 may obtain a plurality of CCVs over time while charging the battery 10 by using constant current for a specific time, in operation S220. The processor 220 may charge or discharge the battery 10 by using large constant current for a short time. In some embodiments, the processor 220 may control the charging device 30 to charge the battery 10 with a constant current of about 0.4 C-rate to about 3 C-rate for about 1 second or less. The measurement unit 210 may basically have a measurement deviation, and a time delay may be added in case of application of small current, making it difficult to specify a slope change of the resistance. Thus, in an embodiment, by providing relatively high current for a short time, the measurement deviation of the resistance may be reduced.

The processor 220 may determine the magnitude of the constant current based on a state of charge (SOC) of the battery 10, the total capacity of the battery 10, etc. In some embodiments, the processor 220 may determine the magnitude of the constant current in inverse proportion to the SOC of the battery 10. This is because application of a large constant current in a high SOC of the battery 10 may damage the battery 10. The processor 220 may use a large constant current for a high total capacity of the battery 10.

The processor 220 may obtain a plurality of CCVs over time at specific time intervals during charging of the battery 10, in operation S230. Under control by the processor 220, the measurement unit 210 may measure the CCV of the battery 10 at specific time intervals and transmit a result to the processor 220. The specific time interval may be 1/10 or less of a selected time for charging the battery 10. For example, the specific time interval may be not more than about 10 msec or about 20 msec. Under control by the processor 220, the measurement unit 210 may measure an initial CCV in 50 milliseconds or less after the constant current is provided to the battery 10. As a measurement period of the initial CCV decreases, the internal resistance may be measured more accurately. This is because, as the measurement period of the initial CCV increases, the measured resistance may reflect a variable resistance, e.g., a diffusion resistance.

The processor 220 may obtain a resistance profile with respect to capacitance by using the OCV and the plurality of CCVs, in operation S230. The processor 220 may calculate a resistance profile with respect to time by using the OCV and the plurality of CCVs, as in Equation 1 below.

$${R}_{t} = \frac{\vert {CCV}_{t} - OCV \vert}{I} \qquad Equation 1$$

Rₜ indicates a resistance at a time t, CCVₜ indicates a CCV at the time t, OCV indicates an OCV, and I indicates a constant current.

The processor 220 may change the resistance profile with respect to time into a resistance profile with respect to capacitance by using Equation 2 below.

$$C = It \qquad Equation 2$$

C indicates a capacitance. I indicates a constant current, and t indicates a time.

A time and a resistance may not one-to-one correspond to each other in the resistance profile with respect to time, but a resistance may one-to-one correspond to a capacitance in the resistance profile with respect to capacitance, such that the internal resistance may be easily determined using the resistance profile with respect to capacitance.

The processor 220 may determine the internal resistance of the battery 10 by using the resistance profile with respect to capacitance, in operation S240. The internal resistance may be included in a resistance corresponding to a capacitance before a lapse of 1/1000 of the total capacitance of the battery in the resistance profile with respect to capacitance. The internal resistance may increase while repetition of charging/discharging of the battery 10, but may be an almost fixed value at the start of charging/discharging, and the variable resistance may be changed by charged or discharged current or voltage. Thus, the internal resistance may be determined within a short time from the start of charging.

The processor 220 may determine the internal resistance in a resistance range in which the difference between resistance change rates of neighboring resistances is a reference value or more in the resistance profile with respect to capacitance. The reference value may be more than about 0, but not more than 1 ohm per amp-hour (Ω/Ah). However, the disclosure is not limited thereto. The reference value may be adjusted by the capacity, type, etc., of the battery 10. The reference value may also be determined using a deep learning model.

As the measurement unit 210 measures the CCV at specific time intervals, the resistance profile with respect to capacitance may be discontinuous data. The processor 220 may linearize the discontinuous resistance profile with respect to capacitance for conversion into a continuous resistance profile with respect to capacitance. The continuous resistance profile with respect to capacitance may include a first region where a resistance change rate difference is a reference value or more and a second region where the resistance change rate difference is less than the reference value. The first region may be indicated by a curved line. The second region may be indicated by a straight line or by a straighter line than the first region. Generally, as a variable resistance, e.g., a diffusion resistance, has a slow response time and a low change rate, a resistance change rate difference may be much affected by the variable resistance after a lapse of 1/1000 of the total capacitance of the battery 10 after application of a constant current in the resistance profile. Thus, the internal resistance may be included in the first region of the resistance profile. A difference between a maximum resistance and a minimum resistance, corresponding to the first region of the resistance profile, may be about 1Ω or less. Thus, the internal resistance obtained from the resistance profile according to an embodiment may have a small deviation, thus improving accuracy.

More precisely, the processor 220 may determine, as the internal resistance, a resistance at a point where the resistance change rate difference is maximum in the resistance range included in the resistance profile, and determine, as the internal resistance, an average resistance of a region (i.e., the first region) indicated by a curved line in the resistance profile. Determining the internal resistance as a range or a specific value in the resistance profile may differ according to the purpose of controlling and managing the battery 10. In some embodiments, in case that the internal resistance is determined to charge the battery 10, the processor 220 may determine, as the internal resistance, a maximum value in the determined internal resistance range. In case that the internal resistance is determined to discharge the battery 10, the processor 220 may determine, as the internal resistance, a minimum value in the determined internal resistance range.

While it is described that the internal resistance is determined during charging of the battery 10, the disclosure is not limited thereto. The internal resistance may also be determined during discharging of the battery 10.

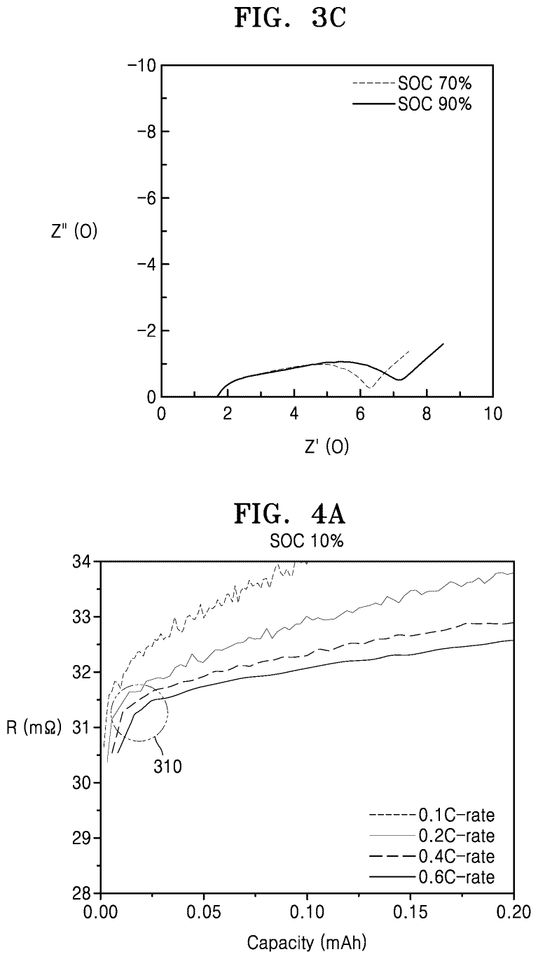

FIG. 3A shows a result of obtaining a resistance profile with respect to capacitance for a battery of 5 mAh having a charging state of 70%, according to an embodiment.

As shown in FIG. 3A, a resistance profile with respect to a small constant current, e.g., about 0.1 C-rate or 0.2 C-rate, is presented by a curved line, making it difficult to determine the internal resistance. On the other hand, the resistance profile with respect to capacitance for a large constant current, e.g., 1 C-rate, 2 C-rate, or 3 C-rate, includes a region (the first region) 310 indicated by a curved line and a region (the second region) 320 indicated by a straight line, making it easy to determine the internal resistance.

The processor 220 may determine a resistance range corresponding to the first region 310 as an internal resistance range or any one of resistances in the resistance range corresponding to the first region 310 as an internal resistance. It may be seen that the internal resistance range may be about 6Ω to about 6.5Ω. In spite of different magnitudes of an applied constant current, the internal resistance may be about 6.5Ω to about 7.5Ω. As the internal resistance range is limited in spite of different magnitudes of the constant current, an internal resistance having a small deviation may be determined.

Thus, by using the resistance profile with respect to capacitance according to an embodiment, an internal resistance having a small deviation may be determined. It may also be expected that an internal resistance having a small deviation may be determined in spite of different magnitudes of the constant current.

FIG. 3B shows a result of obtaining a resistance profile with respect to capacitance for a battery of 5 mAh having a charging state of 90%, according to an embodiment.

Comparing FIG. 3A with FIG. 3B, it may be seen that in spite of different charging states, a resistance profile with respect to capacitance includes a straight region and a curved region at 1 C-rate, 2 C-rate, and 3 C-rate having a large constant current. From FIG. 3B, the internal resistance may fall in a range from about 6.5Ω to about 7.5Ω. In spite of different magnitudes of an applied constant current, an internal resistance having a small deviation may be measured, and by increasing the magnitude of the constant current, the internal resistance may be measured more accurately.

FIG. 3C shows a result of measuring a resistance of a battery, used in FIGS. 3A and 3B, using EIS. Referring to FIG. 3C, an internal resistance of a battery of 5 mAh having a charging state of 70% is about 6.1 mΩ and an internal resistance of a battery of 5 mAh having a charging state of 90% is about 7.1 mΩ. It may be seen that the internal resistance measured by a method according to an embodiment almost matches the internal resistance measured using EIS.

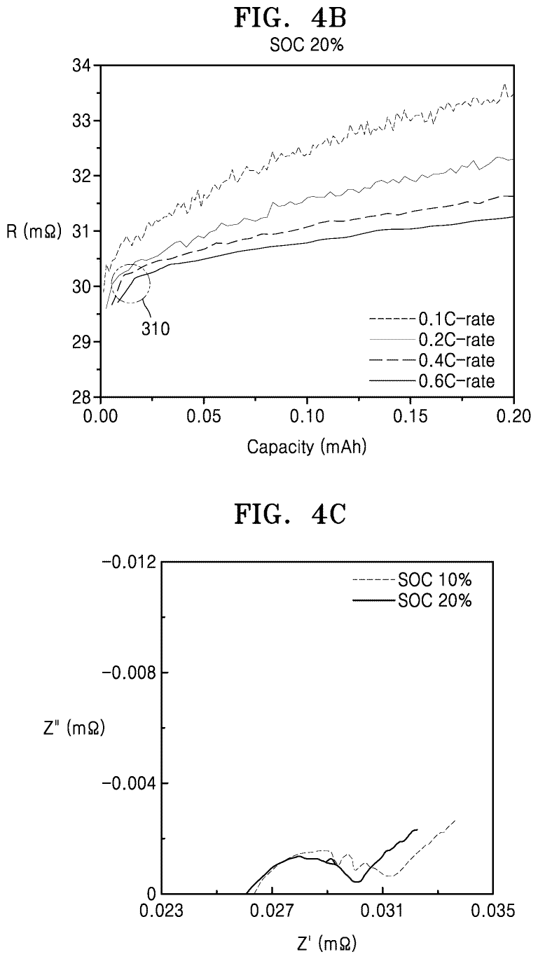

FIG. 4A shows a result of obtaining a resistance profile with respect to capacitance for a battery of 5 Ah having a charging state of 10% according to an embodiment, FIG. 4B shows a result of obtaining a resistance profile with respect to capacitance for a battery of 5 Ah having a charging state of 20% according to an embodiment, and FIG. 4C shows a result of measuring a resistance of a battery used in FIGS. 4A and 4B using EIS.

As shown in FIGS. 4A and 4B, at about 0.1 C-rate and 0.2 C-rate having a small constant current, a curved region and a straight region of a resistance profile with respect to capacitance are not clearly distinguished from each other. However, at 0.4 C-rate and 0.6 C-rate having a large constant current, the resistance profile with respect to capacitance includes a straight region and a curved region, making it easy to determine the internal resistance.

The internal resistance falls within a resistance range corresponding to the curved region, such that the internal resistance of the battery of 5 Ah having a charging state of 10% is about 31 mΩ to about 31.5 mΩ in spite of different magnitudes of the applied constant current. Likewise, the internal resistance of the battery of 5 Ah having a charging state of 20% is about 30 mΩ to about 30.5 mΩ.

FIG. 4C shows a result of measuring a resistance of a battery, used in FIGS. 4A and 4B, using EIS; Referring to FIG. 4C, an internal resistance of a battery of 5 Ah having a charging state of 10% is about 31.1 mΩ and an internal resistance of a battery of 5 Ah having a charging state of 20% is about 30 mΩ. It may be seen that the internal resistance measured by a method according to an embodiment almost matches the internal resistance measured using EIS.

It has been described that the processor determines, as the internal resistance range, a region where the resistance change rate difference is the reference value or more in the resistance profile with respect to capacitance, but the disclosure is not limited thereto. The processor may determine the internal resistance by using a ratio of a time-specific resistance change rate to an initial resistance change rate. The initial resistance change rate may mean a difference between a resistance obtained first and a resistance obtained second after providing a constant current, and the time-specific resistance change rate, e.g., a resistance change rate at the time t, may mean a difference between a resistance obtained at the time t and a resistance obtained at a time (t+1) after providing the constant current. The rate of the time-specific resistance change rate to the initial resistance change rate may converge to 0 as the resistance increases. This is because a variable resistance, e.g., a diffusion resistance, has a great influence upon the resistance change rate above 1/1000 of the capacitance of the battery after application of the constant current.

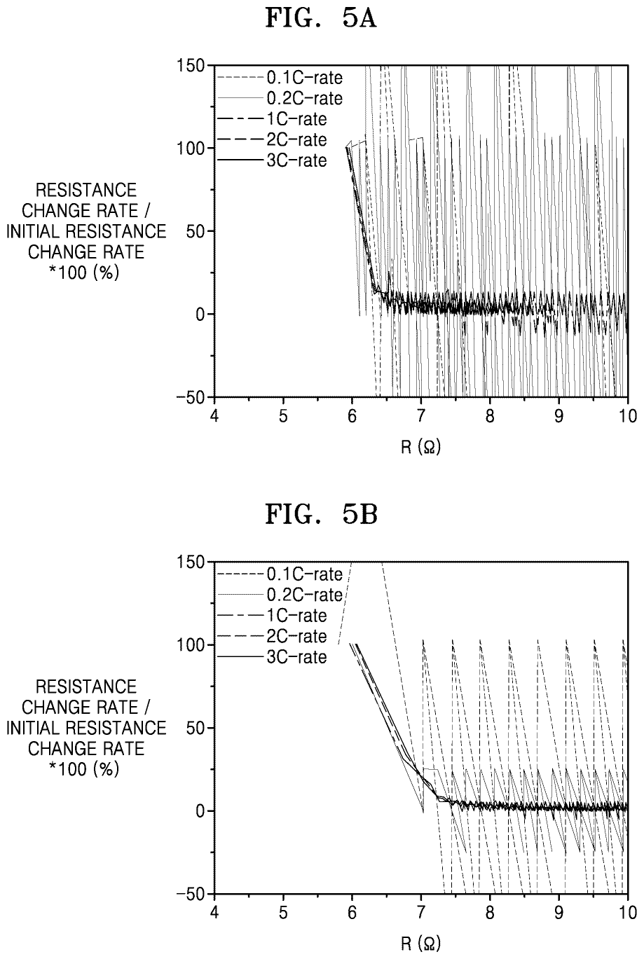

The processor may determine, as the internal resistance, a minimum resistance among resistances where the rate of the time-specific resistance change rate to the initial resistance change rate is a reference value or less. The reference value may be a value in which the rate of the time-specific resistance change rate to the initial resistance change rate is 90% or more. For example, the reference value may be 0% to 30%. The reference value may vary with the type of battery, etc., and may be determined by a deep learning model. FIG. 5A shows a result of obtaining a ratio of a time-specific resistance change rate to an initial resistance change rate from a battery of 5 mAh having a charging state of 70%, according to an embodiment.

As shown in FIG. 5A, the rate of the time-specific resistance change rate to the initial resistance change rate at about 0.1 C-rate and 0.2 C-rate having a small constant current does not converge to a specific rate. However, at 1 C-rate, 2 C-rate, and 3 C-rate having a large constant current, the rate of the time-specific resistance change rate to the initial resistance change rate converges to about 0%. The processor may determine, as the internal resistance, a minimum resistance among resistances where the rate of the time-specific resistance change rate to the initial resistance change rate is equal to the reference value, e.g., about 20%. It may be seen that the internal resistance is about 6Ω to about 6.5Ω at 1 C-rate, 2 C-rate, and 3 C-rate. As the internal resistance range is limited in spite of different magnitudes of the constant current, an internal resistance having a small deviation may be determined.

FIG. 5B shows a result of obtaining a ratio of a time-specific resistance change rate to an initial resistance change rate from a battery of 5 mAh having a charging state of 90%, according to an embodiment.

As shown in FIG. 5B, the rate of the time-specific resistance change rate to the initial resistance change rate at about 0.1 C-rate and 0.2 C-rate having a small constant current does not converge to a specific rate. However, at 1 C-rate, 2 C-rate, and 3 C-rate having a large constant current, the rate of the time-specific resistance change rate to the initial resistance change rate converges to a specific value. The processor may determine, as the internal resistance, a minimum resistance among resistances where the rate of the time-specific resistance change rate to the initial resistance change rate is equal to the reference value, e.g., about 20%. It may be seen that the internal resistance is about 6.5Ω to about 7.5Ω at 1 C-rate, 2 C-rate, and 3 C-rate. As the internal resistance range is limited in spite of different magnitudes of the constant current, an internal resistance having a small deviation may be determined.

As the internal resistance is determined using a plurality of CCVs obtained by applying a relatively large constant current within a short time, e.g., 1 second, the internal resistance having a small deviation may be obtained.

Moreover, even in case that a constant current of different magnitudes being greater than or equal to a specific magnitude is applied, the internal resistance having a small deviation may be obtained.

While the above-described method and apparatus for measuring the internal resistance been described with reference to the embodiments described in the drawings, it will be understood by those of ordinary skill in the art that various modifications and equivalent other embodiments are possible therefrom. Although many matters are specifically described in the foregoing description, they should be interpreted as an example of an embodiment, rather than limiting the scope of the disclosure. Therefore, the scope of the disclosure should not be determined by the described embodiments, but by the technical spirit set forth in the claims.

The internal resistance of the battery with a small deviation may be measured using the resistance profile with respect to capacitance.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A method of measuring an internal resistance of a battery, the method comprising:
obtaining an open circuit voltage of the battery in an equilibrium state;
obtaining a plurality of closed circuit voltages over time while charging or discharging the battery by using a constant current for 1 second or less; and
determining an internal resistance of the battery by using the open circuit voltage and the plurality of closed circuit voltages.

2. The method of claim 1, wherein the battery enters the equilibrium state after a lapse of 20 minutes or more from stop of an operation of the battery.

3. The method of claim 1, wherein the obtaining of the plurality of closed circuit voltages comprises obtaining an initial closed circuit voltage within 50 milliseconds or less after providing the constant current to the battery.

4. The method of claim 1, wherein the obtaining of the closed circuit voltage comprises obtaining the plurality of closed circuit voltages at intervals of a specific time after start of charging or discharging of the battery using the constant current.

5. The method of claim 4, wherein the specific time is 20 milliseconds or less.

6. The method of claim 1, wherein the constant current differs with a state of charge of the battery.

7. The method of claim 6, wherein the constant current is in inverse proportion to the state of charge of the battery.

8. The method of claim 1, wherein the constant current is 0.4 C-rate to 3 C-rate.

9. The method of claim 1, wherein the determining of the internal resistance of the battery comprises:
obtaining a resistance profile with respect to time by using the open circuit voltage and the plurality of closed circuit voltages;
converting the resistance profile with respect to time into a resistance profile with respect to capacitance; and
determining the internal resistance of the battery by using the resistance profile with respect to capacitance.

10. The method of claim 9, wherein the resistance profile with respect to capacitance comprises a first region in which a resistance change rate difference between adjacent resistances is a reference value or more and a second region in which the resistance change rate difference is less than the reference value, and
the internal resistance of the battery falls within a resistance range corresponding to the first region.

11. The method of claim 10, wherein a difference between a maximum resistance and a minimum resistance in the resistance range corresponding to the first region is 1 ohm or less.

12. The method of claim 10, wherein, in the resistance profile with respect to capacitance, the first region has a capacitance less than that of the second region.

13. The method of claim 10, wherein the first region is a curved region, and the second region is a straight region.

14. The method of claim 1, wherein the internal resistance of the battery falls within a resistance range corresponding to a capacitance before 1/1000 of a total capacitance of the battery in the resistance profile with respect to capacitance.

15. The method of claim 1, wherein the determining of the internal resistance of the battery comprises:
determining a resistance profile with respect to time by using the open circuit voltage and the plurality of closed circuit voltages;
obtaining a ratio of a time-specific resistance change rate to an initial resistance change rate from the resistance profile with respect to time; and
determining the internal resistance of the battery by using the ratio of the time-specific resistance change rate to the initial resistance change rate.

16. The method of claim 15, wherein the internal resistance is a minimum resistance in which the ratio of the time-specific resistance change rate to the initial resistance change rate is a reference value or less.

17. The method of claim 16, wherein the reference value is 0% to 30%.

18. A battery management system comprising:
a measurement unit configured to measure a closed circuit voltage of a battery in an equilibrium state and measure a plurality of closed circuit voltages of the battery over time for a selected time during which the battery is charged or discharged with a constant current; and
a processor configured to obtain a resistance profile with respect to capacitance by using the open circuit voltage and the plurality of closed circuit voltages and determine an internal resistance of the battery from the resistance profile with respect to capacitance.

19. The battery management system of claim 18, wherein the selected time is 1 second or less.

20. The battery management system of claim 18, wherein the constant current is 0.4 C-rate to 3 C-rate.
